(19) United States
(12) Patent Application Publication
(10) Pub. No.: US 2007/0108626 A1
(43) Pub. Date: May 17, 2007

(54) FLIP-CHIP INTEGRATED CIRCUIT PACKAGING METHOD

(76) Inventors: Chien Liu, Kao-Hsiung City (TW); Meng-Jen Wang, Ping-Tung Hsien (TW)

Correspondence Address: NORTH AMERICA INTELLECTUAL PROPERTY CORPORATION, P.O. BOX 506, MERRIFIELD, VA, 22116, US

(21) Appl. No.: 11/420,228

(22) Filed: May 25, 2006

(30) Foreign Application Priority Data
Nov. 16, 2005 (TW) 094140310

(51) Int. Cl. H01L 23/48

(52) U.S. Cl. 257/778

(57) ABSTRACT

A flip-chip integrated circuit (IC) packaging method includes providing a carrier which has a top surface and a bottom surface and providing a plurality of IC dies, each die having a back side and being mounted on the top surface of carrier by flip chip bonding. The method further includes attaching a first piece of tape on the back side of the IC dies, providing a packaging material to package the IC dies and a partial area of the top surface of the carrier, and executing a saw singulation process to obtain a plurality of IC packaging structures.

### BACKGROUND OF THE INVENTION

1. Field of the Invention

The present invention relates to a flip-chip integrated circuit (IC) packaging method, and more particularly, to a packaging method including IC dies which have uncovered back sides.

2. Description of the Prior Art

As the integrity of IC chip and the number of electronic components in the IC chip increase, the quantity of heat generated from operation of the IC chip also increases. How heat can be dissipated effectively is a challenge in the design of packaging structures.

For IC packaging structures, especially for flip-chip quad flat no-lead (FC-QFN) packaging structures, a flip-chip package p1 utilizes a packaging material p30 to package an entire IC chip p20 and cover the surface of a lead frame p10 (as shown in FIG. 1). In order to solve the heat dissipation problem of this structure, the prior art usually includes a heat dissipation module (not shown in the figure) on the flip-chip package p1 near the IC chip p20. Thus, a conductive path is provided for the heat generated from operating the IC chip p20 to dissipate through the heat dissipation module. However, because the packaging material p30 of the flip-chip package p1 seals the entire IC chip p20, the heat dissipation module can only be positioned on the packaging material p30 that is set on a back side of the IC chip p20. Therefore, the heat is conducted indirectly through the packaging material p30, and the efficiency of heat dissipation is greatly reduced.

### SUMMARY OF THE INVENTION

It is therefore an objective of the present invention to provide a flip-chip IC packaging method to solve the above-mentioned problem. Because the present invention leaves uncovered back sides of IC dies, a heat dissipation module, such as a heat dissipation plate, can be positioned on the back sides of the IC dies, and heat can be directly conducted from the back sides of the IC dies to the heat dissipation module. As a result, the present invention can prevent heat from transferring through the packaging material, and provide a better efficiency of heat dissipation.

According to the above-mentioned purpose, a flip-chip IC packaging method is provided. First, a carrier that has a top surface and bottom surface is provided. Subsequently, a plurality of IC dies is provided. Each die has a back side, and is mounted on the top surface of carrier by flip-chip bonding. Next, a first piece of tape is attached to the back sides of the IC dies. Thereafter, a packaging material is provided to package the IC dies and a partial area of the top surface of the carrier. Finally, a saw singulation process is executed to obtain a plurality of IC packaging structures.

In addition, the flip-chip IC packaging method further comprises a step of removing the first piece of tape before the step of executing the saw singulation process.

In addition, the carrier provided in the above-mentioned method further comprises a second piece of tape attached to the bottom surface of the carrier.

Additionally, the carrier is a lead frame of flip-chip package.

Otherwise, the carrier can be a lead frame of quad flat no-lead (QFN) package.

Furthermore, the first piece of tape or the second piece of tape can comprise heat-resistant tape.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a cross-sectional schematic diagram of a prior art flip-chip package.

FIG. 2A, FIG. 2B, FIG. 2C, FIG. 2D and FIG. 2E are cross-sectional schematic diagrams of a flip-chip IC packaging method according to a preferred embodiment of present invention.

FIG. 3 is a top-view schematic diagram of FIG. 2C.

FIG. 4 is a top-view schematic diagram of FIG. 2E.

FIG. 5 is a top-view schematic diagram of the combination of the carrier and the IC dies in the flip-chip IC packaging method according to the preferred embodiment of present invention.

FIG. 6 is a cross-sectional schematic diagram along line A-A of FIG. 5.

FIG. 7 is a schematic diagram of removing the first piece of tape in the flip-chip IC packaging method before the step of executing the saw singulation process according to the preferred embodiment of present invention.

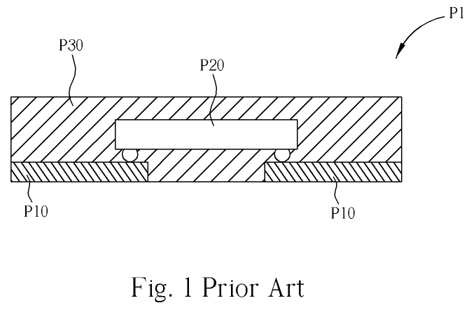

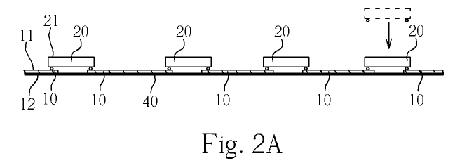

### DETAILED DESCRIPTION

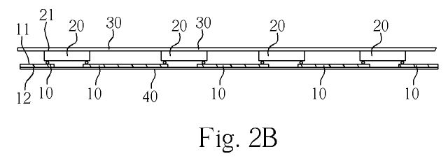

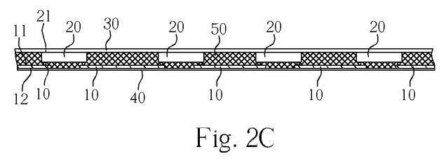

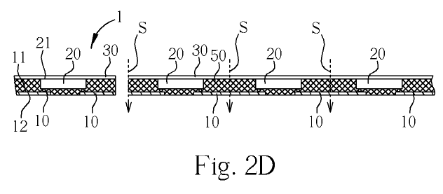

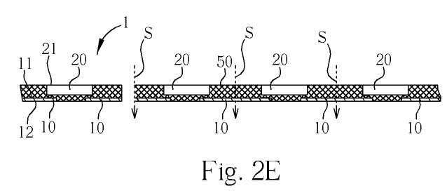

Please refer to FIG. 2A, FIG. 2B, FIG. 2C, FIG. 2D and FIG. 2E. FIG. 2A, FIG. 2B, FIG. 2C, FIG. 2D and FIG. 2E are cross-sectional schematic diagrams of a flip-chip IC packaging method according to a preferred embodiment of present invention. In the packaging method, a carrier 10 is first provided. The carrier 10 can be in the form of a lead frame of a flip-chip package or a lead frame of QFN package, etc. In addition, the carrier 10 has a top surface 11 for placing semiconductor components, such as the IC dies, and a bottom surface 12 that is opposite to the top surface 11.

As shown in FIG. 2A, a plurality of IC dies 20 is provided. Each IC die 20 is mounted on a predetermined position on the top surface 11 of the carrier 10 by flip-chip bonding, and electrically connects to the carrier 10. Each IC die 20 has a back side.

Subsequently, as shown in FIG. 2B, a first piece of tape 30 which has a larger area covers and adheres to the back side of each die 20. The first piece of tape 30 should be heat-resistant tape that can sustain high temperature, so the first piece of tape 30 still can maintain its functions, such as fixity or adhesion, even at a high temperature in the following processes.

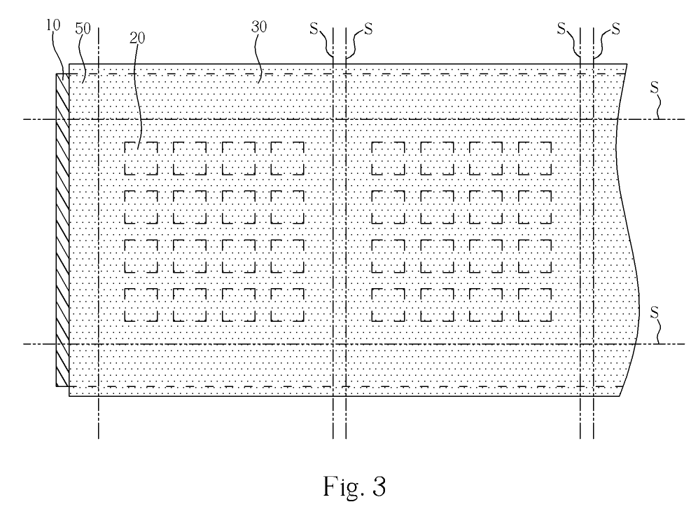

As shown in FIG. 2C and FIG. 3, next, a space between the first piece of tape 30 and the bottom surface 12 of the carrier 10 is filled with a packaging material 50. Because the first piece of tape 30 adheres to the back sides 21 of the IC dies 20, the first piece of tape 30 can function as a wall to keep the packaging material 50 underneath the back sides 21 of the IC dies 20. Furthermore, there can be a mold (not shown in the figure) against the bottom surface 12 of the carrier 10, or further a second piece of tape 40 with large area adhering to the bottom surface 12 of the carrier 10 (as shown in FIG. 2B and FIG. 2C). Thus, the space among the bottom surface 12 of the carrier 10, the back sides 21 of the IC dies 20, and a partial area of the top surface 11 can be filled and sealed with the packaging material 50.

Partial area of the top surface 11 of the carrier 10, which is not sealed, can be the exposed region of the leads (not shown in the figure) of the carrier 10.

Thereafter, as shown in FIG. 2D, after the step of removing the second piece of tape 40, a saw singulation process is executed along scribe lines S to obtain a plurality of IC packaging structures.

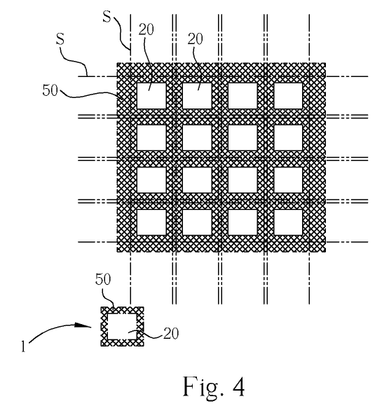

Next, as shown in FIG. 2E and FIG. 4, the first piece of tape 30 is removed.

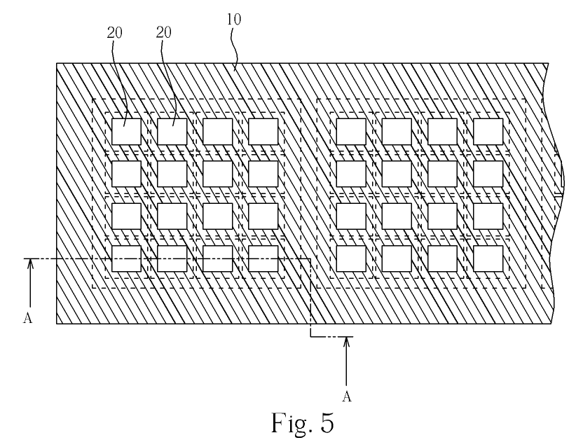

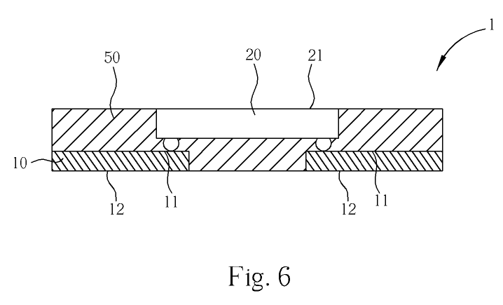

The flip-chip IC packaging structure 1 (as shown in FIG. 5 and FIG. 6) obtained by the above-mentioned processes allows a heat dissipation module (not shown in the figure) to directly contact the uncovered back side 21 of the IC dies 20, so as to obtain the best efficiency of heat dissipation.

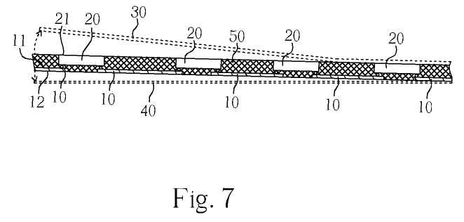

Of course, the above-mentioned first piece of tape 30 and second piece of tape 40 both can be removed before the step of executing the saw singulation process (as shown in FIG. 7).

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A flip-chip integrated circuit (IC) packaging method comprising:
providing a carrier which has a top surface and a bottom surface;
providing a plurality of IC dies, each die having a back side and being mounted on the top surface of carrier by flip chip bonding;
attaching a first piece of tape on the back side of the IC dies;
providing a packaging material to package the IC dies and a partial area of the top surface of the carrier; and
executing a saw singulation process to obtain a plurality of IC packaging structures.

2. The flip-chip IC packaging method of claim 1 further comprising a step of removing the first piece of tape before the step of executing the saw singulation process.

3. The flip-chip IC packaging method of claim 1 further comprising a step of removing the first piece of tape after the step of executing the saw singulation process.

4. The flip-chip IC packaging method of claim 1, wherein the carrier provided further comprises a second piece of tape attached on the bottom surface of the carrier.

5. The flip-chip IC packaging method of claim 1, wherein the carrier is a lead frame of flip-chip package.

6. The flip-chip IC packaging method of claim 1, wherein the carrier is a lead frame of quad flat no-lead (QFN) package.

7. The flip-chip IC packaging method of claim 1, wherein the first piece of tape comprises heat-resistant tape.

8. The flip-chip IC packaging method of claim 1, wherein the second piece of tape comprises heat-resistant tape.
